(19) United States
(12) Patent Application Publication
(10) Pub. No.: US 2026/0088065 A1
(43) Pub. Date: Mar. 26, 2026

(54) MEMORY DEVICE AND COMPUTING SYSTEM

(71) Applicant: SK hynix Inc., Gyeonggi-do (KR)

(72) Inventors: Jee Hoon KIM, San Jose, CA (US); Hanbo WANG, San Jose, CA (US); Hyung Joon BYUN, San Jose, CA (US); Jason JIANG, San Jose, CA (US)

(21) Appl. No.: 19/231,591

(22) Filed: Jun. 9, 2025

Related U.S. Application Data
(60) Provisional application No. 63/696,985, filed on Sep. 20, 2024.

(30) Foreign Application Priority Data
Apr. 18, 2025 (KR) 10-2025-0051013

(51) Int. Cl. G11C 7/08; G11C 7/10; G11C 7/22

(52) U.S. Cl. CPC G11C 7/08; G11C 7/1039; G11C 7/1096; G11C 7/222

(57) ABSTRACT

A memory device may perform a data copy and a NOT computation through a sense amplifier shared by a first subarray and a second subarray. The memory device may use one of the first subarray and the second subarray as an area for storing data for a computation, may use the other as an area for performing the computation, and may provide a function of easily performing various computations.

### CROSS-REFERENCE TO RELATED APPLICATION

The present application claims priority under 35 U.S.C. 119 to U.S. Patent Application No. 63/696,985, filed on Sep. 20, 2024, and Korean Patent Application No. 10-2025-0051013, filed on Apr. 18, 2025, which is incorporated herein by reference in its entirety.

### BACKGROUND

### 1. Technical Field

Embodiments of the present disclosure relate to a memory device and a computing system.

### 2. Related Art

A memory device may include a plurality of memory cells that store data. The memory device may include a memory controller that controls the operation of the plurality of memory cells. The memory device may be included in various electronic devices. For example, the memory device may be included in a computing system and operate under the control of a processor.

The processor may control the memory device, and may perform a computation using the memory device. For example, the processor may read data stored in the memory device, may perform a computation based on the read data, and may store result data according to the computation in the memory device.

As the amount of computations performed by the processor increases, the amount of data transmitted and received between the processor and the memory device may increase. Since the bandwidth between the processor and the memory device is limited, measures capable of improving the performance of a computation by the processor is required.

### SUMMARY

The tasks of embodiments of the present disclosure are not limited to the tasks mentioned in this specification, and other tasks not mentioned will be clearly understood by those skilled in the art from the description below.

Embodiments of the present disclosure are directed to providing measures capable of improving the operational performance of a computing system including a memory device and a processor while providing a computation function by the memory device.

In an embodiment, a memory device may include: a first subarray including a plurality of first memory cells; a second subarray including a plurality of second memory cells; and at least one sense amplifier configured to be shared by the first subarray and the second subarray, wherein, during a first period, data duplicating data stored in at least one target memory cell among the plurality of second memory cells is written to at least one temporary memory cell among the plurality of first memory cells, and wherein, during a second period after the first period, negated data of the data stored in the at least one temporary memory cell is written to at least one result memory cell among the plurality of second memory cells.

In an embodiment, a memory device may include: a first subarray including a plurality of first memory cells; a second subarray including a plurality of second memory cells; and at least one sense amplifier configured to be shared by the first subarray and the second subarray. A majority function computation is performed based on data stored in at least two first memory cells connected to the same column, among the plurality of first memory cells, or based on data stored in at least two second memory cells connected to the same column, among the plurality of second memory cells. A NOT computation on data stored in the plurality of first memory cells or the plurality of second memory cells is performed using the at least one sense amplifier.

In an embodiment, a computing system may include: a processor configured to perform a first data processing; and a computational memory device configured to communicate with the processor and perform a second data processing. The computational memory device includes: a first subarray including a plurality of first memory cells; a second subarray including a plurality of second memory cells; and at least one sense amplifier configured to be shared by the first subarray and the second subarray. Each of the at least one sense amplifier includes: a copy control transistor electrically connected to at least one of the plurality of first memory cells and at least one of the plurality of second memory cells, turned on during a first period, and turned off during a second period after the first period; and at least one amplifier electrically connected to the copy control transistor, turned off during the first period, and turned on during the second period.

According to the embodiments of the present disclosure, a computation function may be provided by using the basic structure of a memory device, and the operational performance of a computing system including the memory device and a processor may be improved.

Effects of embodiments of the present disclosure are not limited to those mentioned above, and other effects not mentioned will be clearly understood by those skilled in the art from the description of claims.

### BRIEF DESCRIPTION OF THE DRAWINGS

The present disclosure will be more fully understood from the detailed description to be made below and the accompanying drawings, which are provided for illustration only and are not intended to limit the present disclosure.

FIG. 1 is a diagram illustrating an example of the schematic configuration of a memory device according to embodiments of the present disclosure.

FIG. 2A and FIG. 2B are diagrams illustrating an example of the structure of a memory cell array included in a memory device according to embodiments of the present disclosure.

FIG. 3 is a diagram illustrating an example of the structure of a sense amplifier included in a memory device according to embodiments of the present disclosure.

FIG. 4 is a diagram illustrating an example of a scheme in which a memory device according to embodiments of the present disclosure performs a computation.

FIG. 5 and FIG. 6 are diagrams illustrating an example in which the memory device operates according to the scheme illustrated in FIG. 4.

FIG. 7A and FIG. 7B are diagrams illustrating an example of the structure of a sense amplifier according to embodiments of the present disclosure.

FIG. 8A to FIG. 8D are diagrams illustrating an example of a scheme in which the sense amplifier illustrated in FIG. 7A and FIG. 7B operates.

FIG. 9 is a diagram illustrating an example of a scheme in which a memory device according to embodiments of the present disclosure performs a computation.

FIG. 10 and FIG. 11 are diagrams illustrating an example in which the memory device operates according to the scheme illustrated in FIG. 9.

FIG. 12 is a diagram illustrating an example in which a computation is performed using a data buffer included in a memory device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

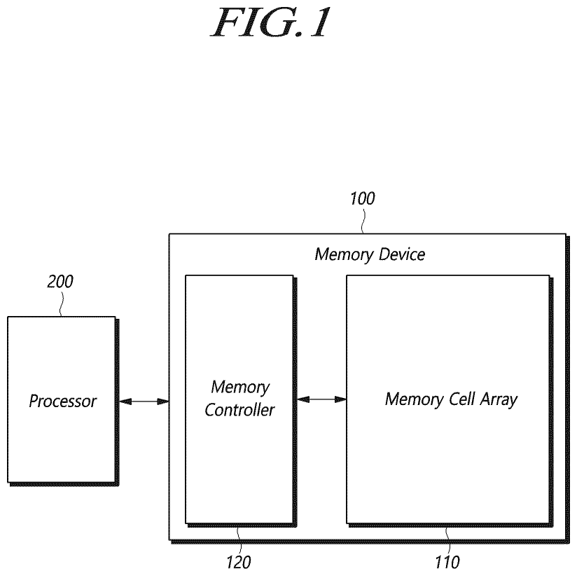

FIG. 1 is a diagram illustrating an example of the schematic configuration of a memory device 100 according to embodiments of the present disclosure.

Referring to FIG. 1, the memory device 100 may include a memory cell array 110 and a memory controller 120.

The memory cell array 110 may include a plurality of memory cells that store data. The memory cell array 110 may include a plurality of word lines and a plurality of bit lines for the operation of the memory cells. The word lines may control the operation timing of the memory cells. The bit lines may be used to write data to the memory cells or read data written to the memory cells. Each memory cell may include at least one circuit element such as a transistor or a capacitor, and components included in the memory cell may be various depending on the type of the memory device 100.

The memory controller 120 may control the operation of the memory cell array 110. The memory controller 120 may control an operation of writing data to the memory cell array 110 or reading data written to the memory cell array 110. Depending on the type of the memory device 100, the memory controller 120 may control a refresh operation on the memory cells or an operation of erasing data written to the memory cells.

The memory controller 120 may control the operation of the memory cell array 110 according to a command received from outside the memory device 100. As the case may be, the memory controller 120 may control the operation of the memory cell array 110 on the basis of its own command.

The memory controller 120 may control the operation of the memory cell array 110 according to a command transmitted by, for example, a processor 200. Depending on the command of the processor 200, the memory controller 120 may write data to the memory cell array 110 or read data written to the memory cell array 110 and provide the read data to the processor 200. The processor 200 and the memory device 100 may be collectively referred to as a computing system.

The processor 200 may be a processing device such as, for example, a central processing unit (CPU), a graphics processing unit (GPU), a neural processing unit (NPU) and a tensor processing unit (TPU), but is not limited thereto.

As the case may be, the processor 200 may be referred to as a host device. For example, the host device may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a telematics network, a radio frequency identification (RFID) device, a mobility device (e.g., a vehicle, a robot or a drone) capable of traveling under human control or autonomous driving, etc. Alternatively, the host device may be a virtual/augmented reality device that provides a 2D or 3D virtual reality image or augmented reality image. In addition to the examples described above, the host device may be any one of various electronic devices that require the memory device 100 capable of storing data for data processing.

The host device may include at least one operating system. The operating system may manage and control overall functions and operations of the host device, and may control the interoperation between the host device and the memory device 100. The operating system may be classified into a general operating system and a mobile operating system depending on the mobility of the host device.

The memory controller 120 and the host device or the processor 200 may be devices that are separated from each other. As the case may be, the memory controller 120 and the host device may be implemented by being integrated into one device. All functions of the memory controller 120 may be implemented by being integrated into the host device, or some functions of the memory controller 120 may be implemented by being integrated into the host device. In the following, for the sake of convenience in explanation, as a case where the memory controller 120 and the host device are devices that are separated from each other, a case where the memory controller 120 is disposed inside the memory device 100 will be described as an example, but embodiments of the present disclosure are not limited thereto.

The type of the memory device 100 may be selected from various types (and combinations) of memory devices. The memory device 100 may be, for example, volatile memory such as DRAM, SDRAM, DDR SDRAM or LPDDR SDRAM, but embodiments of the present disclosure are not limited thereto. The memory device 100 may be nonvolatile memory such as NAND flash memory, 3D NAND flash memory or NOR flash memory. As the case may be, the memory device 100 may include volatile memory and nonvolatile memory.

The memory device 100 may be one of various types of memory such as resistive RAM, phase change memory, magnetoresistive memory, ferroelectric memory or spin transfer torque memory.

As the case may be, the memory device 100 may be processing-in-memory or compute-in-memory that includes a computation function or a data processing function. A component that performs a computation function in the memory device 100 may be located inside or outside a bank including at least a part of the memory cell array 110. When the component that performs the computation function is located outside the bank, the component may be located adjacent to the bank or in an area separate from the bank.

In addition, in particular embodiments, the memory device 100 may provide a computation function using the memory cell array 110. In order to perform a computation function using the memory cell array 110, a separate component may be additionally disposed in the memory cell array 110. Alternatively, a computation function may be provided using the structure of memory cells for storing data, without an additional component disposed in the memory cell array 110.

When the memory device 100 provides a computation function, the memory device 100 may perform a part of a computation by the processor 200 and provide a computation result to the processor 200. The memory controller 120 may control whether the memory device 100 performs a computation function, a period for performing the computation function, etc. As a computation function is provided by the memory device 100, the operational performance of the computing system that performs data processing using the memory device 100 may be improved.

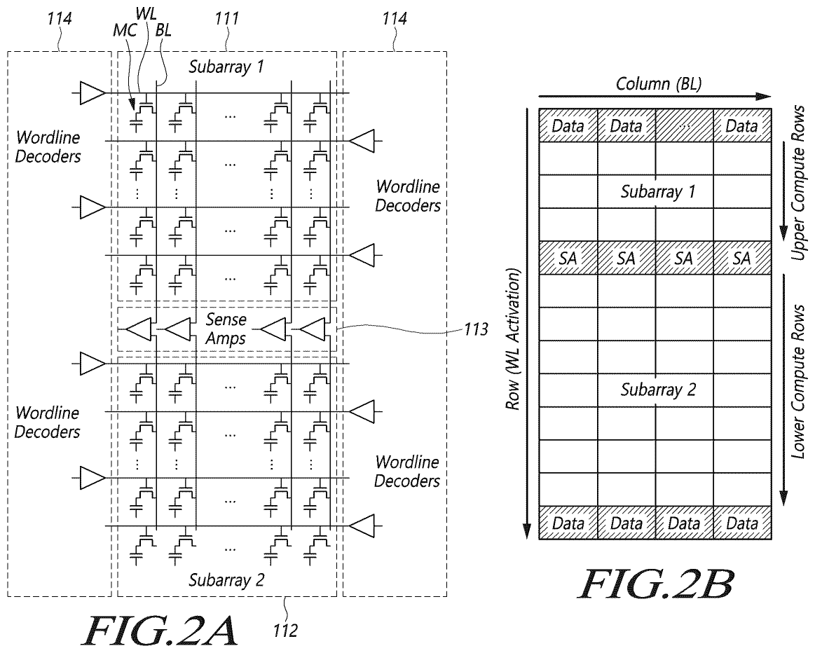

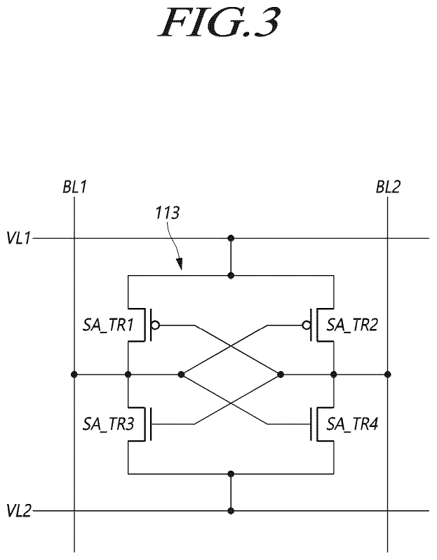

FIG. 2A and FIG. 2B are diagrams illustrating an example of the structure of the memory cell array 110 included in the memory device 100 according to embodiments of the present disclosure. FIG. 3 is a diagram illustrating an example of the structure of a sense amplifier (Sense Amp(s) or SA) 113 included in the memory device 100 according to embodiments of the present disclosure.

Referring to FIG. 2A and FIG. 2B, the memory cell array 110 may include a plurality of memory cells MC. Each memory cell may include a transistor and a capacitor. The memory cell may be disposed in an area where a word line WL and a bit line BL intersect. The word line may be disposed, for example, in a first direction. The bit line may be disposed in a second direction intersecting the first direction. For example, the first direction may be a row direction and the second direction may be a column direction, but are not limited thereto.

The memory cell array 110 may include at least one sense amplifier 113 that is located between memory cells. The memory cell array 110 may include a word line decoder 114 that outputs signals for driving word lines. For example, the sense amplifier 113 may be electrically connected to at least two bit lines. For example, the word line decoder 114 may be electrically connected to at least two word lines. A computation operation may be performed using memory cells and at least one circuit that is disposed in the memory cell array 110.

For example, the memory cell array 110 may include a first subarray 111 (subarray 1) and a second subarray 112 (subarray 2). The first subarray 111 may include a plurality of first memory cells. The first subarray 111 may include word lines and bit lines for driving the first memory cells.

The second subarray 112 may include a plurality of second memory cells. The second subarray 112 may include word lines and bit lines for driving the second memory cells.

The first subarray 111 and the second subarray 112 may share the sense amplifier 113. The sense amplifier 113 may be located between the first subarray 111 and the second subarray 112. The sense amplifier 113 may be electrically connected to at least one of the bit lines disposed in the first subarray 111. The sense amplifier 113 may be electrically connected to at least one of the bit lines disposed in the second subarray 112. The bit line of the first subarray 111 and the bit line of the second subarray 112 that are connected to the sense amplifier 113 may be the same column, but are not limited thereto.

The sense amplifier 113 may include at least one circuit element such as a transistor, and may be electrically connected to at least one voltage line other than the bit lines.

For example, referring to FIG. 3, the sense amplifier 113 may include a first sense transistor SA_TR1, a second sense transistor SA_TR2, a third sense transistor SA_TR3 and a fourth sense transistor SA_TR4. The first sense transistor SA_TR1 and the second sense transistor SA_TR2 may be, for example, P-type transistors. The third sense transistor SA_TR3 and the fourth sense transistor SA_TR4 may be, for example, N-type transistors.

The sense amplifier 113 may be electrically connected to bit lines BL1 and BL2. The bit line BL1 may be a bit line that is electrically connected to first memory cells disposed in the first subarray 111. The bit line BL2 may be a bit line that is electrically connected to second memory cells disposed in the second subarray 112.

The gate node of the first sense transistor SA_TR1 and the gate node of the third sense transistor SA_TR3 may be electrically connected to the bit line BL2. The source node or drain node of the first sense transistor SA_TR1 and the drain node or source node of the third sense transistor SA_TR3 may be electrically connected to the bit line BL1.

The gate node of the second sense transistor SA_TR2 and the gate node of the fourth sense transistor SA_TR4 may be electrically connected to the bit line BL1. The source node or drain node of the second sense transistor SA_TR2 and the drain node or source node of the fourth sense transistor SA_TR4 may be electrically connected to the bit line BL2.

The sense amplifier 113 may be electrically connected to at least one voltage line, and, for example, may be electrically connected to voltage lines VL1 and VL2. For example, the voltage line VL1 may provide a high potential voltage, and the voltage line VL2 may provide a low potential voltage. At least some of the sense transistors SA_TR1, SA_TR2, SA_TR3 and SA_TR4 may be turned on depending on the voltage levels of the bit lines BL1 and BL2 to increase or decrease the voltage levels of the bit lines BL1 and BL2. For example, when the voltage level of the bit line BL1 is a level that turns on the fourth sense transistor SA_TR4 and turns off the second sense transistor SA_TR2, the voltage level of the bit line BL2 may decrease as the fourth sense transistor SA_TR4 is turned on. Because the voltage level of the bit line BL2 decreases, the first sense transistor SA_TR1 may be turned on and the third sense transistor SA_TR3 may be turned off. Because the first sense transistor SA_TR1 is turned on, the high potential voltage of the voltage line VL1 may be supplied to the bit line BL1, and the voltage level of the bit line BL1 may increase. By such an operation scheme, according to the operation of the sense amplifier 113, data stored in the memory cells connected to the bit lines BL1 and BL2 may be read.

In addition, the memory cell array 110 may provide a computation function using the first subarray 111, the second subarray 112 and the sense amplifier 113. At least one of the first subarray 111 and the second subarray 112 may be used as an area for storing data used for a computation. At least one of the first subarray 111 and the second subarray 112 may be used as an area for performing a computation and storing result data according to the computation. Because the sense amplifier 113 is electrically connected to the first subarray 111 and the second subarray 112, the sense amplifier 113 may provide a computation function while controlling data movement between the first subarray 111 and the second subarray 112.

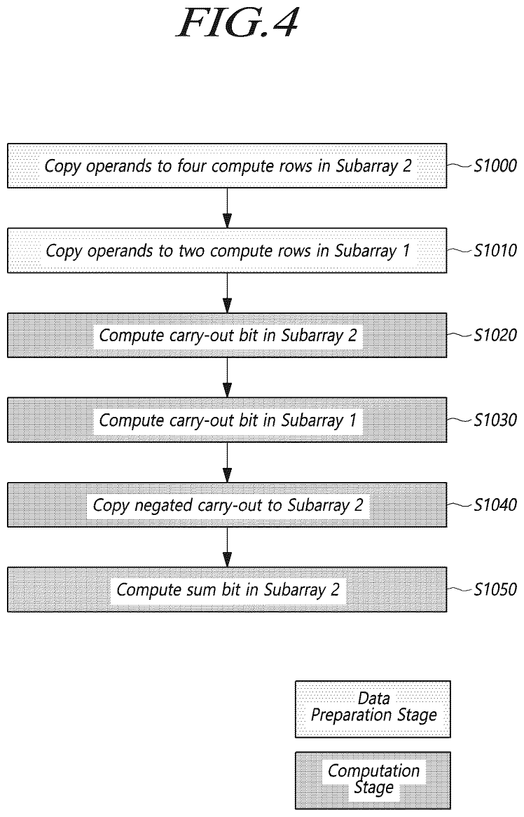

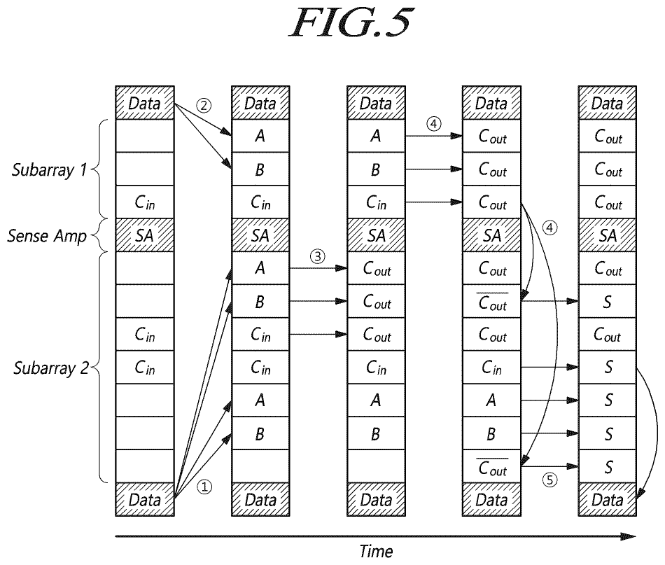

FIG. 4 is a diagram illustrating an example of a scheme in which the memory device 100 according to embodiments of the present disclosure performs a computation.

Referring to FIG. 4, the memory device 100 may perform a computation using the first subarray 111 (subarray 1) and the second subarray 112 (subarray 2) of the memory cell array 110. The memory device 100 may perform a computation using first memory cells and second memory cells, which are connected to the same column, among the first memory cells included in the first subarray 111 and the second memory cells included in the second subarray 112. The first memory cells and the second memory cells connected to the same column may be electrically connected to the same sense amplifier 113.

The memory device 100 may perform an operation of preparing operand data and an operation of performing a computation, for the first subarray 111 and the second subarray 112.

For example, the memory device 100 may copy operand data to two sets of compute rows in the second subarray 112 during a first period (S1000). The memory device 100 may copy operand data to one set of compute rows in the first subarray 111 (S1010). The memory device 100 may perform a computation using the operand data copied to the first subarray 111 and the second subarray 112.

For example, the memory device 100 may compute a carry-out bit in the second subarray 112 (S1020). The carry-out bit may mean a data bit that is computed using the operand data copied (written) to the second subarray 112. For example, a majority function computation using at least two operand data copied to the second subarray 112 may be performed. The majority function computation may mean a computation that outputs a value occupying a larger proportion among the operand data, as a final result value. For example, when two of three operand data are 1 and one is 0, the result value of the majority function computation may be 1. 1 may be stored as a carry-out bit.

The memory device 100 may compute a carry-out bit in the first subarray 111 (S1030). The carry-out bit that is computed using the operand data stored in the first subarray 111 may be the same as the carry-out bit computed in the second subarray 112. For a NOT computation on a carry-out bit computed in the second subarray 112, data the same as the carry-out bit computed in the second subarray 112 may be provided as a carry-out bit in the first subarray 111. In an implementation, a carry-out bit that is computed using the operand data stored in the first subarray 111 may be different from a carry-out bit that is computed in the second subarray 112. For example, a carry-out bit in the first subarray 111 may have a value that results by negating a carry-out bit computed in the second subarray 112. In this case, the carry-out bit in the first subarray 111 may be provided to the second subarray 112 as it is without being negated.

The memory device 100 may compute a negated carry-out value in the second subarray 112 (S1040). For example, the memory device 100 may transmit a carry-out bit stored in a first memory cell of the first subarray 111 to the second subarray 112 through the sense amplifier 113. As the first memory cell in which the carry-out bit is stored in the first subarray 111 and the sense amplifier 113 operate, a value that results by negating the carry-out bit stored in the first memory cell may be stored in a second memory cell of the second subarray 112.

The memory device 100 may compute a sum bit based on data stored in second memory cells of the second subarray 112 (S1050). The sum bit may be, for example, result data according to the majority function computation based on data stored in second memory cells as computation targets in the second subarray 112. The memory device 100 may provide a result value using data stored in the second subarray 112.

In this way, the memory device 100 may perform the majority function computation using the first subarray 111 and the second subarray 112. The memory device 100 may perform the NOT computation using the sense amplifier 113 that connects the first subarray 111 and the second subarray 112. A computation function may be provided by the memory cell array 110 that performs the majority function computation and the NOT computation. The computation function may be provided without disposing an additional component in the memory cell array 110.

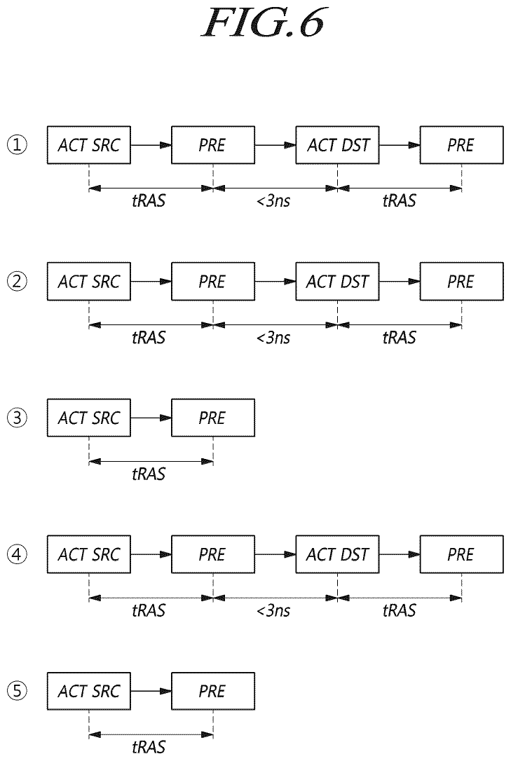

FIG. 5 and FIG. 6 are diagrams illustrating an example in which the memory device 100 operates according to the scheme illustrated in FIG. 4.

Referring to FIG. 5 and FIG. 6, an example is illustrated in which an addition computation is performed using the first subarray 111 (subarray 1) and the second subarray 112 (subarray 2) sharing the sense amplifier 113. An example is illustrated in which data stored in memory cells connected to the same column in the first subarray 111 and the second subarray 112 change over time and a computation is performed.

It may be a state in which carry-in bits are stored in a part of the first memory cells of the first subarray 111 and a part of the second memory cells of the second subarray 112. The carry-in bits may be a part of operand data.

With the carry-in bits stored, other operand data A and B may be written to the second subarray 112 (\textcircled{1}). Each of A and B may be written to two rows in the second subarray 112. In order for A and B to be written to the second subarray 112, an operation of activating the word lines of second memory cells to which A and B are to be written in the second subarray 112 and precharging a bit line may be performed. When memory cells in which A and B are stored and the memory cells to which A and B are to be copied cannot be turned on simultaneously, there may be a predetermined time interval (e.g., 3 ns (nanoseconds)) between activation periods. When memory cells where A and B are stored and the memory cells to which A and B are to be copied may be turned on simultaneously depending on the implementation scheme of a decoder that controls the activation timing of the respective memory cells, there may not be a predetermined time interval. Since the operand data are copied from memory cells where they are stored to the second subarray 112, four copy operations may be performed. In FIG. 6, ACT SRC may mean activating a word line to drive a memory cell in which data for copying is stored. PRE may mean precharging a bit line to connect the memory cell in which data for copying is stored. ACT DST may mean activating a word line to drive a memory cell in which data is copied. tRAS may mean a time interval between the activating operation and the precharging operation.

In addition, A and B may be written to the first subarray 111 (\textcircled{2}). Each of A and B may be written to one row in the first subarray 111. In order for A and B to be written to the first subarray 111, an operation of activating the word lines of first memory cells to which A and B are to be written in the first subarray 111 and precharging a bit line may be performed. Since the operand data are copied from memory cells where they are stored to the first subarray 111, two copy operations may be performed.

A majority function computation based on operand data stored in the second subarray 112 may be performed (\textcircled{3}). For example, a majority function computation based on the values of A, B and Cin corresponding to a carry-in bit stored in upper three rows in the second subarray 112 may be performed. The word lines of second memory cells where A, B and Cin are stored may be activated. The charges of the second memory cells where A, B and Cin are stored are shared, and carry-out bits Cout based on A, B and Cin may be stored in the second memory cells.

A majority function computation based on operand data stored in the first subarray 111 may be performed (\textcircled{4}). The majority function computation and a NOT computation may be performed successively. For example, a majority function computation based on A, B and Cin stored in upper three rows in the first subarray 111 may be performed, and carry-out bits Cout according to the computation may be stored in first memory cells. Thereafter, the sense amplifier 113 between the first subarray 111 and the second subarray 112 may operate. A first memory cell where a carry-out bit is stored in the first subarray 111 and a second memory cell where data is to be stored in the second subarray 112 may be activated. The first memory cell may be referred to as a temporary memory cell, and the second memory cell may be referred to as a result memory cell. As the temporary memory cell and the result memory cell are activated and the sense amplifier 113 operates, a negated carry-out bit of a carry-out bit Cout stored in the temporary memory cell may be stored in the result memory cell. The negated carry-out bit may be stored in at least two second memory cells included in the second subarray 112.

A majority function computation based on at least some operand data stored in second memory cells of the second subarray 112 may be performed (\textcircled{5}). For example, a majority function computation based on the values of negated carry-out bits, a carry-in bit, A and B may be performed. A sum bit may be generated according to the majority function computation. The sum bit may be stored in the second memory cells where the operand data are stored. The sum bit may be outputted as a result value.

A majority function computation may be performed in the first subarray 111 and the second subarray 112, and a NOT computation may be performed through the sense amplifier 113 between the first subarray 111 and the second subarray 112. In the memory device 100, a computation function may be provided without an additional component disposed in the memory cell array 110.

In addition, in particular embodiments, a data copy through the sense amplifier 113 may be made possible, so that an operation of writing the same data to the first subarray 111 and the second subarray 112 may be easily performed.

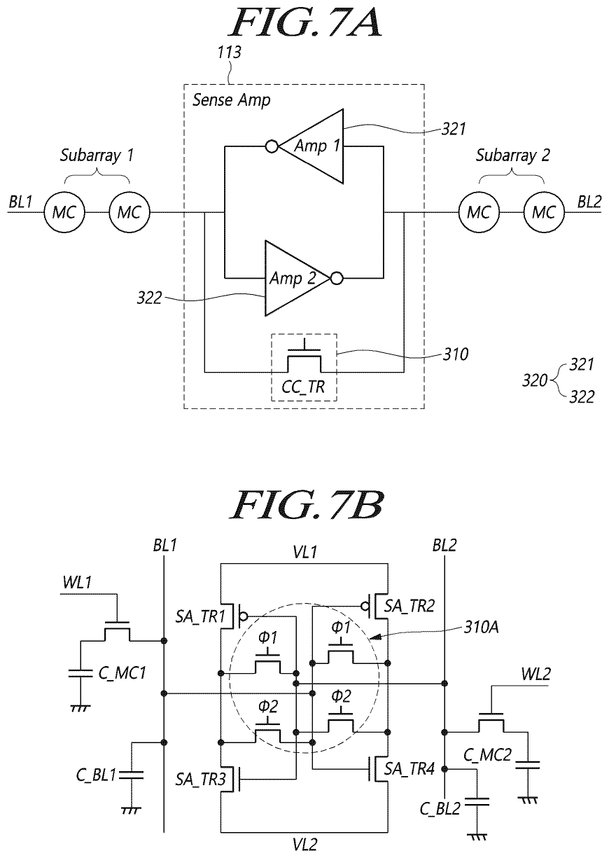

FIG. 7A and FIG. 7B are diagrams illustrating an example of the structure of the sense amplifier 113 according to embodiments of the present disclosure.

Referring to FIG. 7A and FIG. 7B, the sense amplifier 113 may be electrically connected between the first subarray 111 (subarray 1) and the second subarray 112 (subarray 2). The sense amplifier 113 may be electrically connected to a bit line BL1 of the first subarray 111. The sense amplifier 113 may be electrically connected to a bit line BL2 of the second subarray 112. The bit line BL1 disposed in the first subarray 111 may be electrically connected to a first memory cell where a transistor to be driven by a word line WL1 is disposed. A capacitor C_MC1 may be disposed in the first memory cell. A capacitance C_BL1 may be formed on the bit line BL1. The bit line BL2 disposed in the second subarray 112 may be electrically connected to a second memory cell where a transistor to be driven by a word line WL2 is disposed. A capacitor C_MC2 may be disposed in the second memory cell. A capacitance C_BL2 may be formed on the bit line BL2.

The sense amplifier 113 may include a copy control transistor 310. The copy control transistor 310 may be electrically connected between the first subarray 111 and the second subarray 112. The copy control transistor 310 may be electrically connected to the bit line BL1 of the first subarray 111 and the bit line BL2 of the second subarray 112. The copy control transistor 310 may be replace with at least two transistors (i.e., 310A of FIG. 7B) that may control the electrical connection between the bit line BL1 and the bit line BL2 while being controlled by signals Φ1 and Φ2.

The sense amplifier 113 may include a pair of cross-coupled inverters for latching and amplification. In the present specification, it may be described that the sense amplifier 113 may include at least one amplifier 320. The sense amplifier 113 may include a first amplifier (Amp 1) 321 and a second amplifier (Amp 2) 322. For example, the first amplifier 321 may negate data of a second memory cell connected to the bit line BL2 of the second subarray 112 and output the negated data. For example, the second amplifier 322 may negate data of a first memory cell connected to the bit line BL1 of the first subarray 111 and output the negated data.

A data copy may be performed between the first subarray 111 and the second subarray 112 by the copy control transistor 310. A NOT computation may be performed between the first subarray 111 and the second subarray 112 through the amplifier 320.

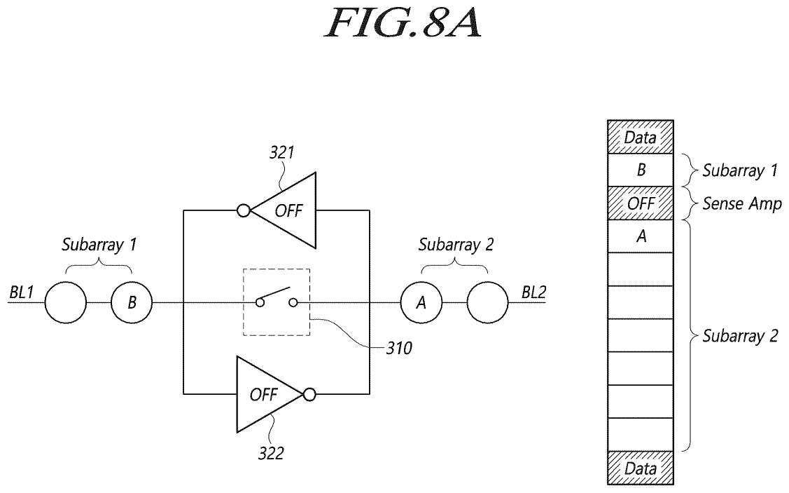

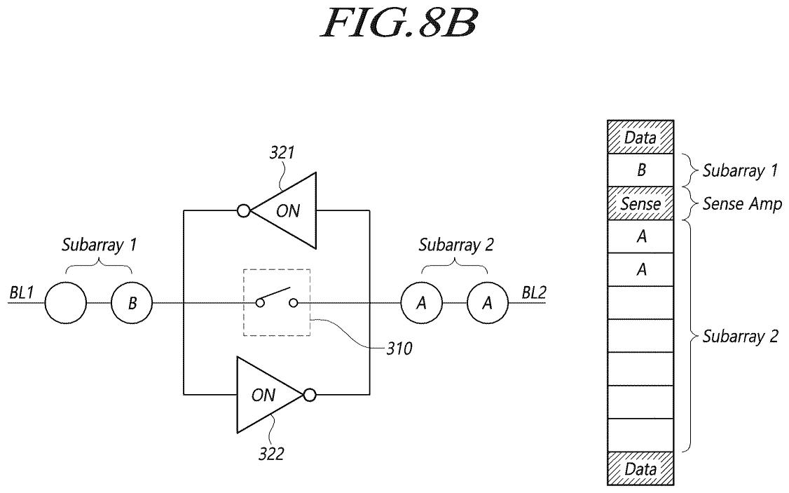

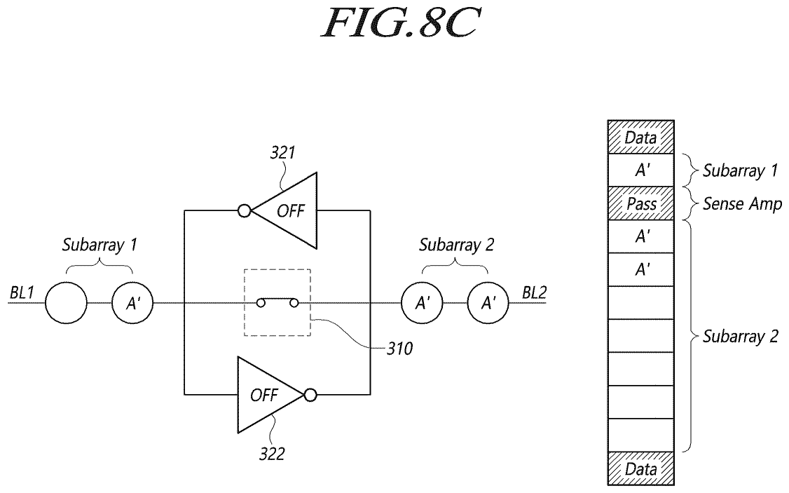

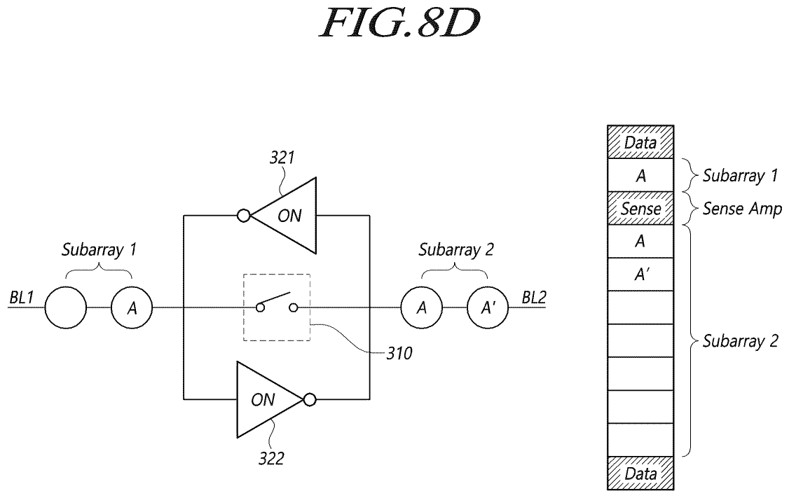

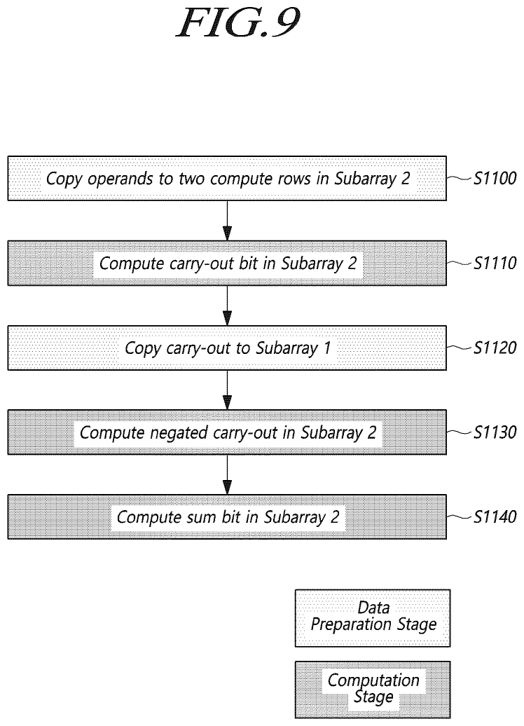

FIG. 8A to FIG. 8D are diagrams illustrating an example of a scheme in which the sense amplifier 113 illustrated in FIG. 7A and FIG. 7B operates.

Referring to FIG. 8A, a state in which data B is stored in the first subarray 111 (subarray 1) and data A is stored in the second subarray 112 (subarray 2) is illustrated as an example.

A first memory cell where the data B is stored and a second memory cell where the data A is stored may be electrically connected to the same sense amplifier 113. The copy control transistor 310 included in the sense amplifier 113 may be in a turned-off state. The amplifier 320 included in the sense amplifier 113 may be in a turned-off state.

Referring to FIG. 8B, a data copy or a data write may be performed in the second subarray 112. The data A may be written to a second memory cell included in the second subarray 112.

As the data A is written to the second memory cell, the amplifier 320 included in the sense amplifier 113 may be turned on. The copy control transistor 310 included in the sense amplifier 113 may maintain the turned-off state.

Referring to FIG. 8C, in the state in which data are written to the first subarray 111 and the second subarray 112, the copy control transistor 310 of the sense amplifier 113 may be turned on. The amplifier 320 of the sense amplifier 113 may be turned off.

As the copy control transistor 310 is turned on, a data copy between the first memory cell and the second memory cells electrically connected to the sense amplifier 113 may be performed. The voltage levels of the bit line BL1 connected to the first memory cell and the bit line BL2 connected to the second memory cells may be shared. A majority function computation based on data stored in the first memory cell and data stored in the second memory cells may be performed. New data A′ may be written to the first memory cell and the second memory cells on the basis of the data B stored in the first memory cell and the data A stored in the second memory cells. For example, when A is 1, A′ may indicate 1 or a value corresponding to ⅔ of a high potential voltage. When A is 0, A′ may indicate 0 or a value corresponding to ⅓ of the high potential voltage. Because two operand data of three operand data in the majority function computation are A, A′ may have the same value as A.

Referring to FIG. 8D, the copy control transistor 310 of the sense amplifier 113 may be turned off. The amplifier 320 of the sense amplifier 113 may be turned on. A refresh operation may be performed on the first memory cell of the first subarray 111. A refresh operation may be performed on a part of the second memory cells of the second subarray 112. For example, a refresh operation may be performed on the first memory cell and the second memory cell located adjacent to the sense amplifier 113. It may become a state in which the data A is written to the first memory cell. A state in which the data A is written to the second memory cell may be maintained. It may become a state in which the data A′ according to the majority function computation is stored in the second memory cell. A′ and A may be the same value. A data copy or a majority function computation may be performed according to the operation of the copy control transistor 310. A NOT computation may be performed according to the operation of the amplifier 320. Various computations based on the memory cell array 110 may be performed according to the operation of the sense amplifier 113 including the copy control transistor 310 and the amplifier 320.

FIG. 9 is a diagram illustrating an example of a scheme in which the memory device 100 according to embodiments of the present disclosure performs a computation.

Referring to FIG. 9, the memory device 100 may copy operand data to two compute rows in the second subarray 112 (subarray 2) during a first period (S1100). The memory device 100 may perform a computation based on the operand data copied to the second subarray 112 to compute a carry-out bit (S1110). For example, the memory device 100 may perform a majority function computation based on data stored in the second subarray 112 and compute a carry-out bit.

The memory device 100 may copy the carry-out bit of the second subarray 112 to the first subarray 111 (subarray 1) (S1120). For example, the memory device 100 may turn on the copy control transistor 310 included in the sense amplifier 113 that electrically connects the first subarray 111 and the second subarray 112.

According to the operation of the copy control transistor 310, the value of the carry-out bit stored in the second subarray 112 may be copied to the first subarray 111. An operation of writing operand data to the first subarray 111 to copy the value of the carry-out bit to the first subarray 111 may be omitted. Because the carry-out bit is generated in the second subarray 112 and is copied to the first subarray 111, a majority function computation may not be performed in the first subarray 111. The first subarray 111 may perform only a function of storing a carry-out bit for an intermediate computation. An operation for storing operand data in the first subarray 111 or for computing operand data may not be performed. The first subarray 111 may perform only a function of providing an area for a NOT computation.

During a second period, a negated carry-out bit may be stored in the second subarray 112 (S1130). For example, during the second period, the amplifier 320 of the sense amplifier 113 that electrically connects the first subarray 111 and the second subarray 112 may operate. A negated carry-out bit of a carry-out bit stored in the first subarray 111 may be stored in the second subarray 112.

The memory device 100 may perform a majority function computation based on operand data or negated carry-out bits stored in the second subarray 112, and may compute a sum bit (S1140). In a process in which a computation using the second subarray 112 is performed, an operation for using the first subarray 111 in the computation may be simplified. A computation function using the second subarray 112 may be performed while the operation of the first subarray 111 is minimized.

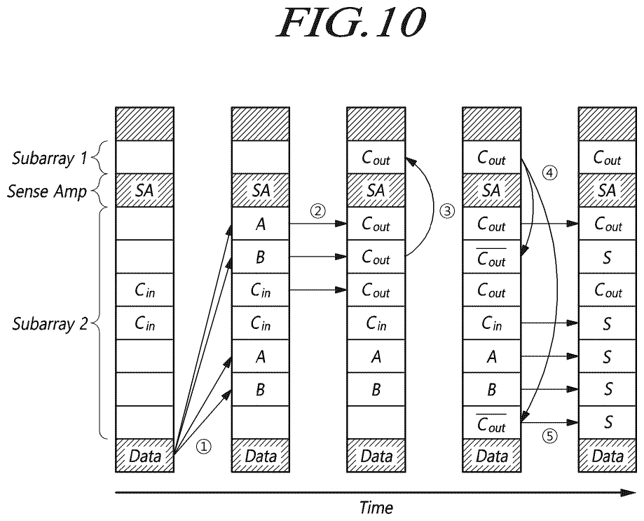

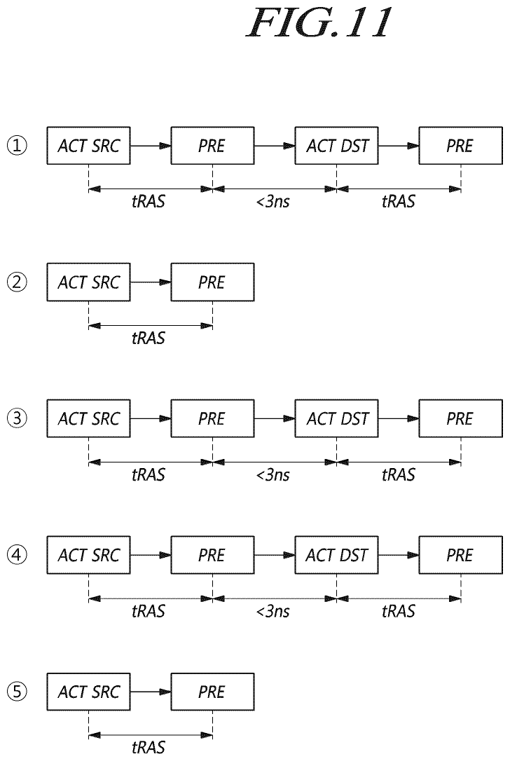

FIG. 10 and FIG. 11 are diagrams illustrating an example in which the memory device 100 operates according to the scheme illustrated in FIG. 9.

Referring to FIGS. 10 and 11, a computation may be performed using the first subarray 111 (subarray 1) and the second subarray 112 (subarray 2) connected to the sense amplifier 113. In a state in which carry-in bits Cin are stored in at least some of the second memory cells included in the second subarray 112, a data copy for a computation, etc. may be performed.

For example, during a first period, operand data A and B may be written to second memory cells of the second subarray 112 (\textcircled{1}). The second memory cells to which the operand data A and B are written may be referred to as target memory cells. In order for writing the operand data A and B, word lines connected to the target memory cells may be activated and a bit line connected to the target memory cells may be precharged. A computation based on a carry-in bit and the operand data stored in the target memory cells may be performed. In FIG. 11, ACT SRC may mean activating a word line to drive a memory cell in which data for copying is stored. PRE may mean precharging a bit line to connect the memory cell in which data for copying is stored. ACT DST may mean activating a word line to drive a memory cell in which data is copied. tRAS may mean a time interval between the activating operation and the precharging operation.

During a period in which the operand data A and B are written to the second subarray 112, data may not be written to the first subarray 111.

A computation based on the operand data written to the second subarray 112 may be performed (\textcircled{2}). For example, a majority function computation based on a carry-in bit and the operand data A and B may be performed. Word lines connected to second memory cells that are computation targets may be activated, a bit line may be precharged, and a result value according to the majority function computation may be stored in the corresponding second memory cells. A carry-out bit Cout according to the computation may be stored in the target memory cells.

The carry-out bit stored in a target memory cell may be copied to a first memory cell of the first subarray 111 (\textcircled{3}). The first memory cell to which the carry-out bit is copied may be referred to as a temporary memory cell. The temporary memory cell may be connected to the same column as the target memory cell.

In order to copy the carry-out bit stored in the target memory cell, the target memory cell may be activated in the second subarray 112. During a period in which the carry-out bit is copied, the amplifier 320 included in the sense amplifier 113 connected between the first subarray 111 and the second subarray 112 may be turned off. The copy control transistor 310 included in the sense amplifier 113 may be turned on. An operation for storing operand data in the temporary memory cell of the first subarray 111 or an operation for computing a carry-out bit in the first subarray 111 may not be performed. Data the same as (for example, duplicate or matching) the carry-out bit computed according to the operation of the second subarray 112 may be copied to the first subarray 111.

During a second period, a negated carry-out bit of the carry-out bit stored in the temporary memory cell of the first subarray 111 may be written to at least one second memory cell of the second subarray 112 (\textcircled{4}). The second memory cell to which the negated carry-out bit is written may be referred to as a result memory cell. The result memory cell may be the same as or different from the target memory cell. The result memory cell may be connected to the same column as the temporary memory cell.

During the second period, the amplifier 320 included in the sense amplifier 113 between the first subarray 111 and the second subarray 112 may be turned on. The copy control transistor 310 included in the sense amplifier 113 may be in a turned-off state. According to the operation of the amplifier 320 of the sense amplifier 113, the negated carry-out bit of the carry-out bit stored in the temporary memory cell of the first subarray 111 may be written to the result memory cell of the second subarray 112.

A computation based on operand data stored in at least some of the second memory cells of the second subarray 112 may be performed (\textcircled{5}). For example, a majority function computation based on a carry-in bit, a carry-out bit, a negated carry-out bit and data A and B stored in second memory cells of the second subarray 112 may be performed. A sum bit, as a result value of the majority function computation, may be stored in the second memory cells. The sum bit as a final result of the computation may be provided.

A data copy and a NOT computation may be performed according to the operations of the copy control transistor 310 and the amplifier 320 of the sense amplifier 113 connected between the first subarray 111 and the second subarray 112. An operation for writing operand data to the first subarray 111 or a computation operation for computing a carry-out bit in the first subarray 111 may not be performed, and a majority function computation, a NOT computation, etc. may be performed through the second subarray 112. The first subarray 111 may be used to temporarily store data for the NOT computation, and various computations may be easily performed using the operation of the sense amplifier 113 and the operation of the second subarray 112.

In accordance with an embodiment, a data copy for a computation may be performed using a buffer that is located outside the first subarray 111 and the second subarray 112.

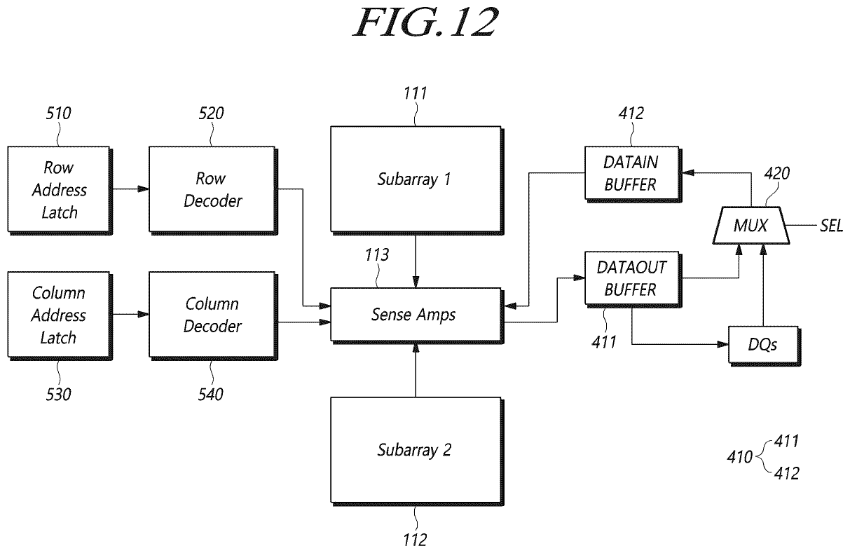

FIG. 12 is a diagram illustrating an example in which a computation is performed using a data buffer 400 included in the memory device 100 according to embodiments of the present disclosure.

Referring to FIG. 12, the memory device 100 may include a first subarray 111 (subarray 1), a second subarray 112 (subarray 2), and a sense amplifier 113 that is connected between the first subarray 111 and the second subarray 112. The memory device 100 may include at least one data buffer 400 that is used to store data in the first subarray 111 or the second subarray 112 or to read data stored in the first subarray 111 or the second subarray 112. For example, the memory device 100 may include a data output buffer (DATAOUT BUFFER) 411 and a data input buffer (DATAIN BUFFER) 412. The data output buffer 411 and the data input buffer 412 may be electrically connected through a multiplexer (MUX) 420.

The memory device 100 may include various circuits that output values instructing the operations of the first subarray 111, the second subarray 112 and the sense amplifiers (Sence Amps) 113. For example, the memory device 100 may include a row address latch 510, a row decoder 520, a column address latch 530, and a column decoder 540. The row address latch 510 may receive and latch a row address that indicates a row to operate in the memory cell array 110. The row decoder 520 may decode the row address latched by the row address latch 510, and may output a signal that indicates a row to operate. The column address latch 530 may receive and latch a column address that indicates a column to operate in the memory cell array 110. The column decoder 540 may decode the column address latched by the column address latch 530, and may output a signal that indicates a column to operate.

When performing a computation using the first subarray 111, the second subarray 112 and the sense amplifiers 113, the memory device 100 may perform a data copy between the first subarray 111 and the second subarray 112 using the data buffer 410.

For example, during a first period, the memory device 100 may store operand data or a carry-out bit stored in a target memory cell of the second subarray 112 in the data output buffer 411. The memory device 100 may operate the multiplexer 420, and thereby, may copy the operand data, etc. stored in the data output buffer 411 to the data input buffer 412. During the first period, the data output buffer 411 and the data input buffer 412 may be electrically connected by the multiplexer 420.

The operand data, etc. stored in the data input buffer 412 may be provided to the first subarray 111. The operand data, etc. may be stored in a temporary memory cell of the first subarray 111.

During a second period, the amplifier 320 of the sense amplifiers 113 may be turned on, and negated data of data stored in the temporary memory cell of the first subarray 111 may be stored in a result memory cell of the second subarray 112. During the second period, the multiplexer 420 may not operate or may electrically isolate (i.e., disconnect) the data output buffer 411 and the data input buffer 412.

Through the data buffer 410, a data copy between the first subarray 111 and the second subarray 112 may be easily performed. A NOT computation may be performed through the sense amplifiers 113 between the first subarray 111 and the second subarray 112.

Various computations may be performed using the first subarray 111, the second subarray 112 and the sense amplifiers 113, and the memory device 100 in which a computation function is implemented using the basic structure of the memory cell array 110 storing data may be provided.

Although various embodiments of the present disclosure have been described with particular specifics and varying details for illustrative purposes, those skilled in the art will appreciate that various modifications, additions and substitutions may be made based on what is disclosed or illustrated in the present disclosure without departing from the spirit and scope of the present disclosure as defined in the following claims.

What is claimed is:

1. A memory device comprising:
a first subarray including a plurality of first memory cells;
a second subarray including a plurality of second memory cells; and
at least one sense amplifier configured to be shared by the first subarray and the second subarray,
wherein, during a first period, data duplicating data stored in at least one target memory cell among the plurality of second memory cells is written to at least one temporary memory cell among the plurality of first memory cells, and
wherein, during a second period after the first period, negated data of the data stored in the at least one temporary memory cell is written to at least one result memory cell among the plurality of second memory cells.

2. The memory device according to claim 1, wherein each of the at least one sense amplifier comprises:
a copy control transistor electrically connected to at least one of the plurality of first memory cells and at least one of the plurality of second memory cells, turned on during the first period, and turned off during the second period; and
at least one amplifying circuit electrically connected to the copy control transistor.

3. The memory device according to claim 2, wherein the at least one amplifying circuit is turned off during the first period and is turned on during the second period.

4. The memory device according to claim 1, wherein the at least one target memory cell and the at least one temporary memory cell are electrically connected to a same sense amplifier of the at least one sense amplifier.

5. The memory device according to claim 1, wherein the at least one temporary memory cell and the at least one result memory cell are electrically connected to a sense amplifier of the at least one sense amplifier.

6. The memory device according to claim 1, wherein the at least one target memory cell, the at least one temporary memory cell and the at least one result memory cell are connected to a same column.

7. The memory device according to claim 1, further comprising:
a data buffer configured to, during the first period, store the data stored in the at least one target memory cell and provide the stored data to the at least one temporary memory cell.

8. The memory device according to claim 7, wherein the data buffer comprises:
a data output buffer configured to store the data stored in the at least one target memory cell; and
a data input buffer configured to provide data to the at least one temporary memory cell.

9. The memory device according to claim 8, further comprising a multiplexer configured to:
electrically connect the data output buffer and the data input buffer during the first period; and
electrically disconnect the data output buffer and the data input buffer during a period other than the first period.

10. The memory device according to claim 1, wherein the data stored in the at least one target memory cell is maintained during the first period.

11. The memory device according to claim 1, wherein, during a period between the first period and the second period, data computed based on data stored in at least two first memory cells among the plurality of first memory cells is written to the at least one temporary memory cell.

12. The memory device according to claim 1, wherein, during a third period after the second period, data computed based on data stored in at least one of the plurality of second memory cells and the at least one result memory cell is written to the at least one result memory cell.

13. The memory device according to claim 1, wherein, during the first period, a word line connected to the at least one target memory cell and a word line connected to the at least one temporary memory cell are configured to activate simultaneously or sequentially.

14. The memory device according to claim 1, wherein, during the second period, a word line connected to the at least one temporary memory cell and a word line connected to the at least one result memory cell are configured to activate simultaneously or sequentially.

15. A memory device comprising:
a first subarray including a plurality of first memory cells;
a second subarray including a plurality of second memory cells; and
at least one sense amplifier configured to be shared by the first subarray and the second subarray,
wherein a majority function computation is performed based on data stored in at least two first memory cells connected to a same column, among the plurality of first memory cells, or based on data stored in at least two second memory cells connected to a same column, among the plurality of second memory cells, and
wherein a NOT computation on data stored in the plurality of first memory cells or the plurality of second memory cells is performed using the at least one sense amplifier.

16. The memory device according to claim 15, wherein:
each of the at least one sense amplifier includes a copy control transistor electrically connected to at least one of the plurality of first memory cells and at least one of the plurality of second memory cells; and
a data copy is performed between the first subarray and the second subarray through the copy control transistor that is turned on.

17. The memory device according to claim 16, wherein each of the at least one sense amplifier further includes at least one amplifying circuit that is electrically connected to at least one of the plurality of first memory cells and at least one of the plurality of second memory cells, is turned off when the copy control transistor is turned on, and is turned on when the copy control transistor is turned off.

18. The memory device according to claim 17, wherein the NOT computation is performed when the copy control transistor is turned off and the at least one amplifier is turned on.

19. A computing system comprising:
a processor configured to perform a first data processing; and
a computational memory device configured to communicate with the processor and perform a second data processing,
wherein the computational memory device comprises:
a first subarray including a plurality of first memory cells;
a second subarray including a plurality of second memory cells; and
at least one sense amplifier configured to be shared by the first subarray and the second subarray, and
wherein each of the at least one sense amplifier comprises:
a copy control transistor electrically connected to at least one of the plurality of first memory cells and at least one of the plurality of second memory cells, turned on during a first period, and turned off during a second period after the first period; and
at least one amplifying circuit electrically connected to the copy control transistor, turned off during the first period, and turned on during the second period.

20. The computing system according to claim 19, wherein the processor is configured to:
transmit a write command or a read command for the second subarray to the computational memory device without accessing the first subarray; and
receive result data obtained by the second data processing of the computational memory device.
